(19) United States
(12) Patent Application Publication
(10) Pub. No.: US 2012/0100684 A1
(43) Pub. Date: Apr. 26, 2012

(54) METHOD OF FABRICATING SEMICONDUCTOR DEVICE

(75) Inventors: Ji-Young Min, Seoul (KR); Yu-Gyun Shin, Seongnam-si (KR); Gab-Jin Nam, Seoul (KR); Young-Pil Kim, Hwaseong-si (KR)

(73) Assignee: SAMSUNG ELECTRONICS CO., LTD., Suwon-si (KR)

(21) Appl. No.: 13/280,430

(22) Filed: Oct. 25, 2011

(30) Foreign Application Priority Data
Oct. 25, 2010 (KR) 10-2010-0103937

(51) Int. Cl. H01L 21/336; B82Y 40/00

(52) U.S. Cl. 438/287; 977/755; 257/E21.423

(57) ABSTRACT

A method of fabricating a semiconductor device includes sequentially forming a first gate insulating layer and a second gate insulating layer on a substrate, implanting impurity ions into the substrate and performing a first thermal process for activating the impurity ions to form a source and drain region, and forming a third gate insulating layer on the substrate after the first thermal process has been completed.

### PRIORITY STATEMENT

This application claims priority from Korean Patent Application No. 10-2010-0103937 filed on Oct. 25, 2010 in the Korean Intellectual Property Office, and all the benefits accruing therefrom under 35 U.S.C. 119.

### BACKGROUND

The inventive concept relates to the fabricating of semiconductor devices. In particular, the inventive concept relates to the forming of the gate structure and source and drain regions of a semiconductor device.

In a semiconductor device, a dielectric layer may be used as a gate insulating layer or a capacitor insulating layer of a transistor. In order for a dielectric layer to effectively function as a gate insulating layer or a capacitor insulating layer, the dielectric layer must have appropriate capacitance. The capacitance of a dielectric layer is proportional to the dielectric constant and area of the dielectric layer and is inversely proportional to the thickness of the dielectric layer. Providing the dielectric layer with a greater area to produce a semiconductor device having a higher capacitance is undesirable, however, because the greater area decreases the degree to which the semiconductor devices can be integrated. Thus, semiconductor devices tend to employ high-k dielectric layers.

Meanwhile, the fabricating of a semiconductor device typically may also entail the forming of an insulating layer, other than the aforementioned high-k dielectric layer, between the high-k dielectric layer and a substrate. However, the high temperature of a thermal process used to enhance the characteristics of the insulating layer may degrade the characteristics of the high-k dielectric.

### SUMMARY

According to one aspect of the inventive concept, there is provided a method of fabricating a semiconductor device, comprising: sequentially forming a first gate insulating layer and a second gate insulating layer on a substrate, forming a source and drain region including by implanting impurity ions into a region in the substrate and performing a first thermal process for activating the impurity ions, and forming a third gate insulating layer on the substrate after the first thermal process has been performed.

According to another aspect of the inventive concept, there is provided a method of fabricating a semiconductor device, comprising: sequentially forming a first gate insulating layer, a second gate insulating layer and a dummy gate electrode layer on a substrate, forming a source and drain region including by implanting impurity ions into a region in the substrate and performing a first thermal process to activate the impurity ions, removing the dummy gate electrode layer, and sequentially forming a third gate insulating layer and an electrically conductive gate electrode layer including directly over the area of the substrate from which the dummy gate electrode layer has been removed.

According to still another aspect of the inventive concept, there is provided a method of fabricating a semiconductor device, comprising: sequentially forming a first insulating layer, a second insulating layer, and a dummy electrode layer on a substrate as a stack structure, wherein the second insulating layer is of high-k dielectric material, implanting impurity ions into a region in the substrate using the stack structure as an ion implantation mask, heating the substrate to a temperature within a range of 800 to 1300° C. to activate the impurity ions, removing the dummy gate electrode layer, forming a third insulating layer on the first insulating layer after the heating of the substrate to activate the impurity ions has been completed and the dummy gate electrode layer has been removed, wherein the third insulating layer is also of high-k dielectric material, and forming an electrically conductive layer on the third insulating layer.

### BRIEF DESCRIPTION OF THE DRAWINGS

The above and other features and advantages of the inventive concept will become more apparent inform the detailed description of the preferred embodiments thereof made with reference to the attached drawings in which:

FIGS. 1 to 6 are cross-sectional views sequentially illustrating an embodiment of a method of fabricating a semiconductor device according to the inventive concept;

FIGS. 7 to 9 are cross-sectional views sequentially illustrating intermediate stages of another embodiment of a method of fabricating a semiconductor device according to the inventive concept; and

FIGS. 10 to 14 are cross-sectional views sequentially illustrating intermediate stages of still another embodiment of a method of fabricating a semiconductor device according to the inventive concept.

### DETAILED DESCRIPTION OF THE EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “region in the substrate” may refer to a region of the substrate itself or a region of a layer, e.g., an SiGe layer, that has been formed in the substrate.

It will also be understood that when an element or layer is referred to as being “on” another element or layer, it can be directly on the other element or layer or intervening elements or layers may be present. In contrast, when an element or layer is referred to as being “directly on” another element or layer, there are no intervening elements or layers present.

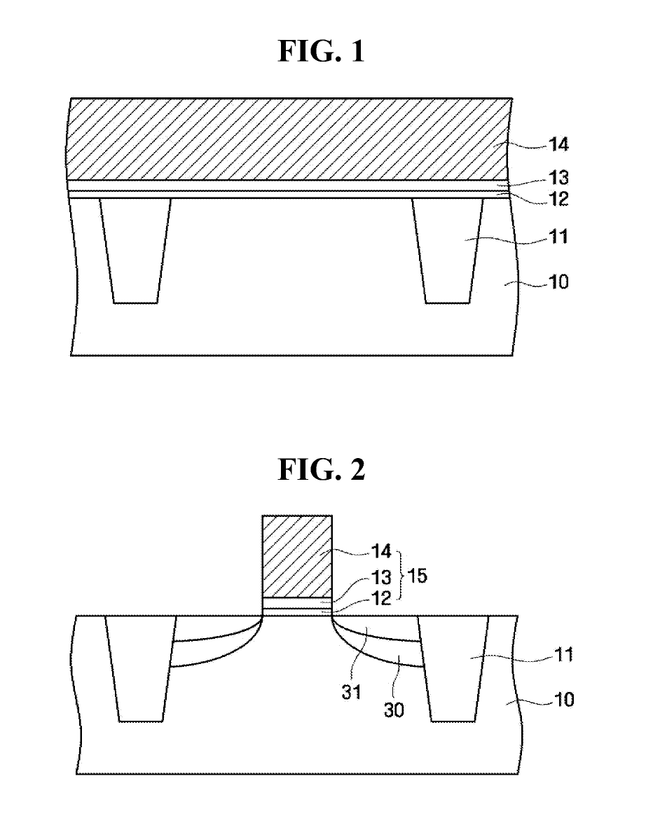

A method of fabricating a semiconductor device according to the inventive concept will now be described with reference to FIGS. 1 to 6.

Referring first to FIG. 1, a device isolation region 11 is formed in a substrate 10 to define an active region. The substrate 10 may be a rigid substrate such as a silicon substrate, a silicon on insulator (SOI) substrate, a gallium arsenic substrate, a silicon germanium substrate, a ceramic substrate, a quartz substrate, or a display glass substrate, or a flexible plastic substrate made of, for example, polyimide, polyethylene terephthalate (PET), polyethylene naphthalate (PEN), polymethyl methacrylate (PMMA), polycarbonate (PC), polyethersulfone (PES), or polyester. The device isolation region 11 may be a field oxide (FOX) or shallow trench isolation (STI) region formed by a local oxidation of silicon (LOCOS) technique.

Subsequently, an ion implantation process for forming a well, adjusting a threshold voltage (V_{T}), preventing a punch-through effect, or forming a channel stopper in a channel region may be performed.

Next, a first gate insulating layer 12, a second gate insulating layer 13, and a dummy gate electrode layer 14 are sequentially formed on the substrate 10. The first gate insulating layer 12 may be comprise a silicon oxide layer, a silicon nitride layer, or a silicon oxynitride layer and may be formed by a thermal oxidation process, or a deposition process such as chemical vapor deposition (CVD), physical vapor deposition (PVD) or atomic layer deposition (ALD).

The second gate insulating layer 13 is formed of a high-k dielectric material. In this example, the second gate insulating layer 13 is formed to a thickness of 5 Å or less. The second gate insulating layer 13 may consist of a single layer of a high-k dielectric material or may be a composite layer. In these respects, the second gate insulating layer 13 may include at least one material selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The dummy gate electrode layer 14 may be made of poly-Si, poly-SiGe, or doped poly-Si, and may be formed by a deposition process. In examples of this embodiment, the dummy gate electrode layer 14 has a thickness of 500 to 2000 Å, but the present embodiment is not limited to the forming of a dummy gate electrode layer to a thickness within such a range.

Referring to FIG. 2, a photoresist pattern (not shown) is formed on the dummy gate electrode layer 14, and a dummy gate stack 15 is formed by etching the dummy gate electrode layer 14, the second gate insulating layer 13 and the first gate insulating layer 12 using the photoresist pattern as an etch mask.

Next, the photoresist pattern is removed and a halo region 30 is formed by implanting halo ions into the substrate 10 using the dummy gate stack 15 as an ion implantation mask. The halo ions may have a conductivity type opposite to that of an impurity ion forming a source and drain region.

Subsequently, a lightly doped source and drain region 31 is formed by implanting ions into the active region of the substrate 10 using the dummy gate stack 15 as an ion implantation mask. In the case of an NMOS, the lightly doped source and drain region 31 is formed by implanting an n-type impurity, e.g., phosphorus (P) or arsenic (As). In the case of a PMOS, the lightly doped source and drain region 31 is formed by implanting a p-type impurity, e.g., boron (B). The lightly doped source and drain region 31 may be formed to a depth less than that of the halo region 30 relative to the upper surface of the substrate 10.

In another example of the present embodiment, the forming of the halo region 30 and the forming of the lightly doped source and drain region 31 are skipped.

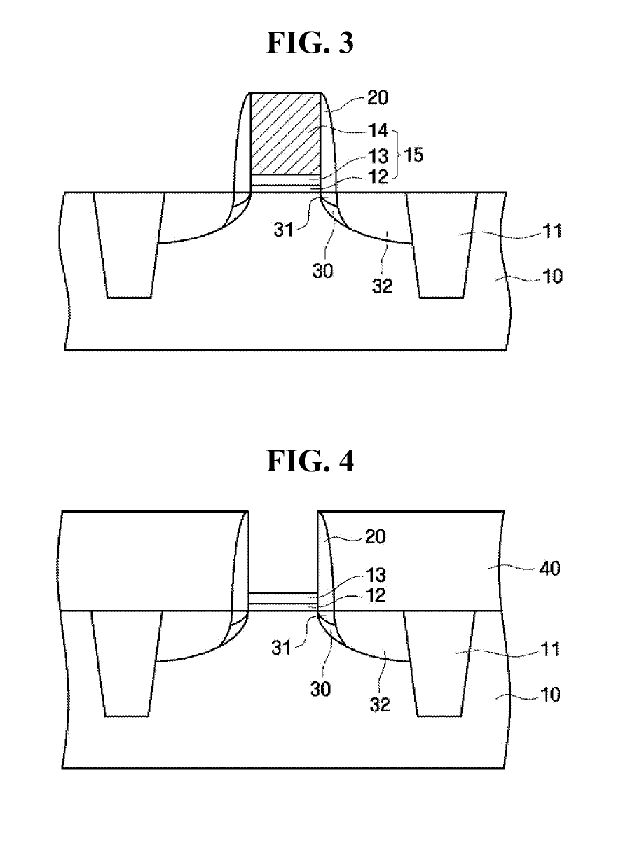

Referring to FIG. 3, a spacer forming insulating layer is formed over the substrate 10 in conformance with the profile of the topography of the dummy gate stack 15. The spacer forming insulating layer is then anisotropically etched, thereby forming a spacer 20 on sidewalls of the dummy gate stack 15. The spacer 20 may be formed of a material having a high etching selectivity with respect to the dummy gate electrode layer 14. For example, the spacer 20 may be formed of silicon nitride.

Next, a heavily doped source and drain region 32 is formed by implanting impurity ions into the substrate using the gate stack and spacer 20 as an ion implantations mask.

A thermal process is subsequently performed to activate impurity ions of the heavily doped source and drain region 32. The thermal process may be rapid thermal annealing (RTA), spike rapid thermal annealing (SRTA), laser spike annealing (LSA) or a flash rapid thermal process (FRTP). In the case of RTA, the thermal process is performed at a temperature in a range of 800 to 900° C. In the case of SRTA, LAS, or FRTP, the thermal process is performed at a temperature in a range of 800 to 1300° C.

Furthermore, the first gate insulating layer 12 and the second gate insulating layer 13 of the dummy gate stack 15 are subjected to the thermal process. At this time, the first gate insulating layer 12 is supplied with oxygen by the second gate insulating layer 13 to remedy interfacial defects, thereby reducing the interface trap density (Dit) of the first gate insulating layer 12. However, the number of oxygen vacancies in the second gate insulating layer 13 increases as a result. Thus, the second gate insulating layer 13 is preferably formed to a thickness that allows the oxygen necessary for remedying the defects in the first gate insulating layer 12 to be supplied and yet, which thickness is small enough to prevent the second gate insulating layer 13 from deteriorating due to too many vacancies being formed therein. An exemplary thickness in these respects is one of 5 Å or less, as mentioned above.

Referring to FIG. 4, an interlayer dielectric layer 40 is formed on the substrate 10 to bury the dummy gate stack 15. The interlayer dielectric layer 40 may be a silicon oxide layer, and may be formed by chemical vapor deposition (CVD) or plasma enhanced chemical vapor deposition (PECVD).

Next, a planarization process is performed until a top surface of the dummy gate electrode layer 14 is exposed. The planarization process may be a chemical mechanical polishing (CMP) or etch back process.

Subsequently, the dummy gate electrode layer 14 is removed. As a result, a recess is defined in the interlayer dielectric layer 40.

The dummy gate electrode layer 14 may be removed by a plasma-based dry etching process and/or a wet etching process employing a hydroxide solution. The plasma-based dry etching process is an etching method in which plasma is produced by ionizing source gas, and a substrate is etched by causing the plasma to collide with the substrate. In an example of the present embodiment in which the plasma-based dry etching process is employed, the source gas is a combination of NF₃, HBr and Cl₂. In examples of the present embodiment in which the wet etching process is employed, the dummy gate electrode layer 14 is treated in a high temperature aqueous solution of ammonium hydroxide or tetraalkyl ammonium hydroxide. However, the wet etching process that may be used is not limited to employing these particular hydroxide solutions.

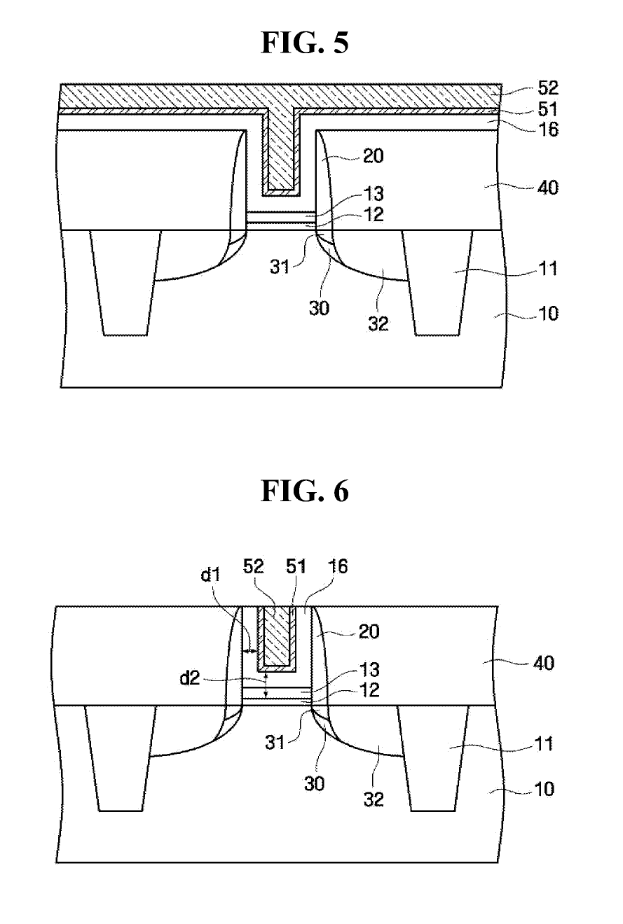

Referring to FIG. 5, a third gate insulating layer 16 is formed over the entire substrate 10 in which the second gate insulating layer 13 is exposed. The third gate insulating layer 16 is formed of high-k dielectric material. The high-k dielectric material may be selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Also, note, the gate insulating layer 16 and the second gate insulating layer 13 may be made of the same high-k dielectric material or different high-k dielectric materials.

Next, a post nitridation annealing (PNA) process for supplying the third gate insulating layer 16 with nitrogen or a post deposition annealing (PDA) process for activating the third gate insulating layer 16 may be performed. In this embodiment, the PNA or PDA process are performed at a temperature of 800° C. or less to prevent the third gate insulating layer 16 from being thermally damaged.

Next, a first gate electrode layer 51 and a second gate electrode layer 52 are sequentially formed over the entire surface of the substrate 10. The first gate electrode layer 51 is a barrier layer made of titanium nitride (TiN) or tantalum nitride (TaN). The second gate electrode layer 52 is made of a metal such as tungsten (W), aluminum (Al), copper (Cu), titanium (Ti) or tantalum (Ta). The first and second gate electrode layers 51 and 52 may be formed by physical vapor deposition, sputtering, or chemical vapor deposition.

Referring to FIG. 6, a planarization process is performed until a top surface of the interlayer dielectric layer 40 is exposed. The planarization process may be a chemical mechanical polishing (CMP) or etch back process.

According to this embodiment of the inventive concept, the third gate insulating layer 16 is formed after the heavily doped source and drain region 32 has been formed, specifically after a thermal process performed at 800° C. or higher for activating the impurity ions constituting the heavily doped source and drain region 32. Otherwise, the number of traps of the high-k dielectric material of the third gate insulating layer 16 would increase, due to the high temperature of the thermal process, to the point that essential characteristics of the high-k dielectric material would deteriorate.

Also, according to the present embodiment, the second gate insulating layer 13 is formed before the thermal process for activating the impurity ions constituting the heavily doped source and drain region 32. As a result, the thickness d1 of the sidewall of the composite gate insulating layer, consisting of high-k dielectric material, is less than the thickness d2 of the bottom wall thereof. In addition, the oxygen concentration of the second gate insulating layer 13 is smaller than that of the third gate insulating layer 16.

In the example described above, the first and second gate insulating layers 12 and 13 are thermally treated by the thermal process whose primary purpose is to activate the ions constituting the heavily doped source and drain region 32. However, in another example of this embodiment, the first and second gate insulating layers 12 and 13 may be subjected to a heat treatment dedicated to reduce the interface trap density (Dit) of the first gate insulating layer 12, and then the ions constituting the heavily doped source and drain region 32 can be activated by performing the above-described thermal process prior to the forming of the third gate insulating layer 16.

Another embodiment of a method of fabricating a semiconductor device according to the inventive concept will now be described with reference to FIGS. 1 to 4 and FIGS. 7 to 9.

The initial part of the method is similar to that shown in and described with reference to FIGS. 1 to 4. Therefore, this part of the method will not be described in detail.

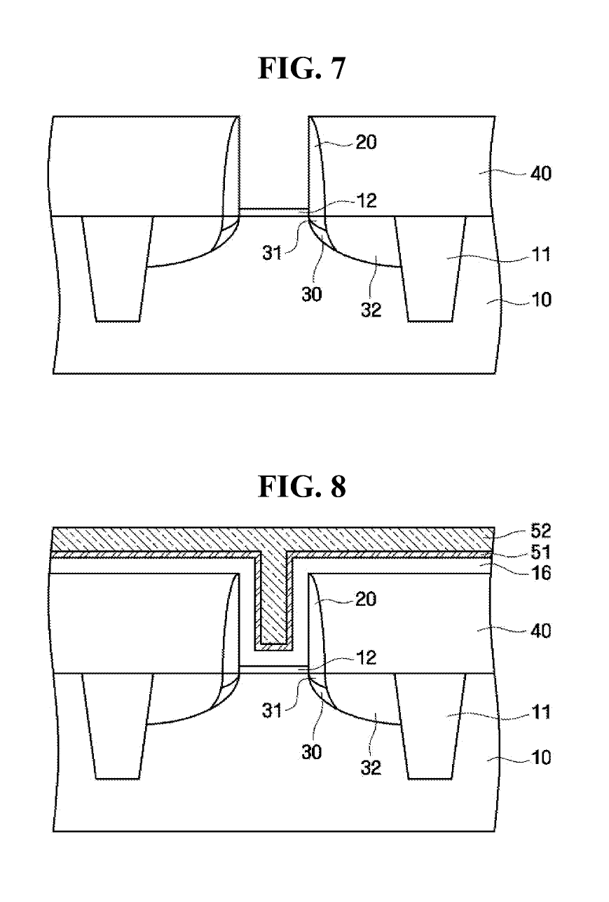

Referring to FIG. 7, the first and second gate insulating layers 12 and 13 are subjected to a heat treatment to reduce the interface trap density (Dit) of the first gate insulating layer 12, and then the second gate insulating layer 13 is removed.

The second gate insulating layer 13 may be removed by wet etching. For example, the second gate insulating layer 13 may be removed using an HF based etching solution. Note, according to this embodiment of the inventive concept, the first gate insulating layer 12 is formed more thickly than in the previously described embodiment because in this embodiment the second gate insulating layer 13 is removed.

The subsequent steps are similar to the corresponding steps described in connection with the previous embodiment, and thus will be only briefly described hereinafter. Referring to FIG. 8, a third gate insulating layer 16 is formed on the substrate 10 atop which the first gate insulating layer 12 is exposed, i.e., the third gate insulating layer 16 is formed after the dummy gate electrode layer 14 and the second gate insulating layer 13 have been removed.

Next, a post nitridation annealing (PNA) process for supplying the third gate insulating layer 16 with nitrogen or a post deposition annealing (PDA) process for activating the third gate insulating layer 16 may be performed. In these cases, the PNA or PDA process is performed at a temperature of 800° C. or less to prevent the third gate insulating layer 16 from being thermally damaged. Next, a first gate electrode layer 51 and a second gate electrode layer 52 are sequentially formed on the substrate 10 including over the third gate insulating layer 16.

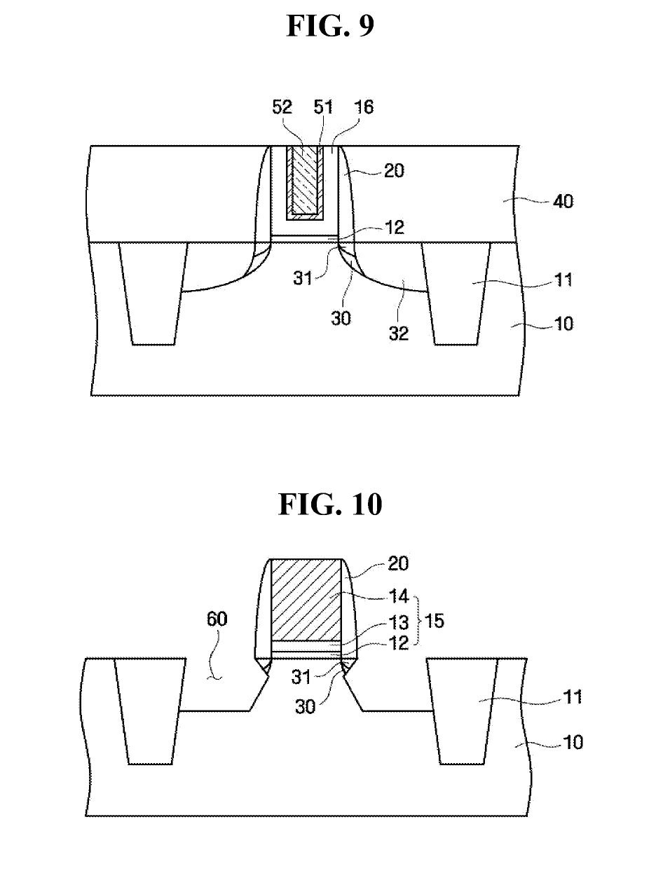

Referring to FIG. 9, a planarization process is performed until a top surface of an interlayer dielectric layer 40 is exposed. The planarization process may be a chemical mechanical polishing (CMP) or etch back process.

Still another embodiment of method of fabricating a semiconductor device according to the inventive concept will be described with reference to FIGS. 1 and 2 and FIGS. 10 to 14.

The initial part of the method is similar to that shown in and described with reference to FIGS. 1 and 2. Therefore, this part of the method will not be described in detail.

Referring to FIG. 10, next, a trench 60 is formed in the substrate 10. In one example of this process, the trench 60 is formed by first dry etching the substrate (i.e., isotropically etching the substrate) using the dummy gate stack and spacer 20 as an etch mask to form a preliminary trench, and then wet etching the resultant structure to expand the preliminary trench. The wet etching may be a crystallographic anisotropic etching process. A KOH, NaOH, NH₄OH, or tetramethyl ammonium hydroxide (TMAH) etching solution may be used to this end.

The use of crystallographic anisotropic etching causes the substrate 10 to be etched at different etching rates according to the crystal orientation of the plane delimiting the surface exposed to the etching solution. For example, if a horizontal plane of the substrate 10 includes a [100] crystalline orientation, a vertical plane of the substrate 10 includes a [110] crystalline orientation, and a diagonal plane of the substrate 10 includes a crystalline orientation, the substrate 10 is etched at varying rates in order of the horizontal plane having [100] crystalline orientation, the vertical plane having [110] crystalline orientation, and the diagonal plane having [111] crystalline orientation. Accordingly, the trench 60 formed by the crystallographic anisotropic etching may have a sigma-like profile adjacent the dummy gate stack, wherein the wall of the substrate 10 delimiting the side of the trench is chevron-shaped.

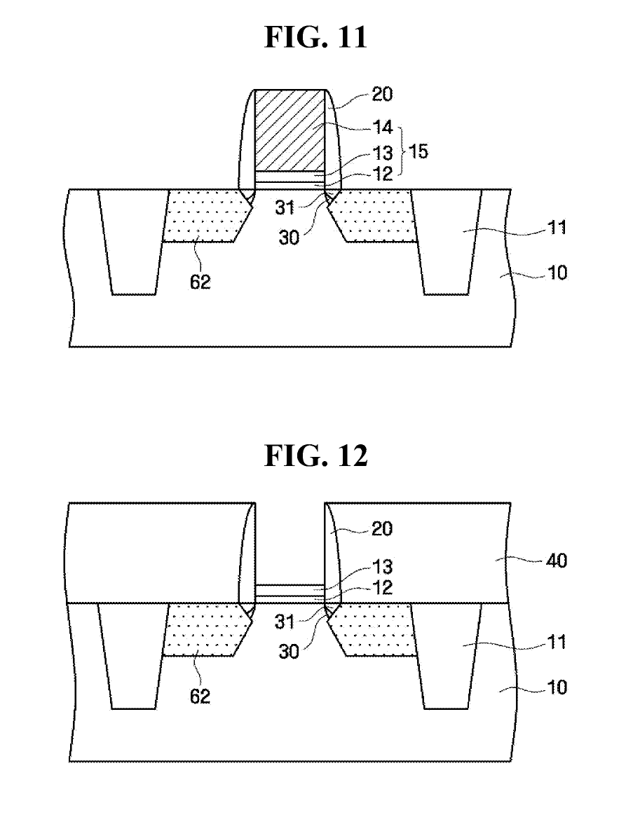

Referring to FIG. 11, an SiGe epitaxial layer 62 is formed in the trench 60 by an epitaxial growth process. The epitaxial growth process may be performed at a temperature in a range of approximately 500 to approximately 900° at 1 to 500 Torr. These conditions may be varied as necessary or desired. In addition, SiH₄, SiH₂Cl₂, SiHCl₃, SiCl₄, SiHxCly (x+y=4), Si(OC₄H₉)₄, Si(OCH₃)₄, or Si(OC₂H₅)₄ may be used as a silicon source gas, and GeH₄, GeCl₄, or GeHxCly (x+y=4) may be used as a Ge source gas in the epitaxial growth process. However, the epitaxial growth process that is employed in this embodiment is not limited to these source gases. Furthermore, the SiGe epitaxial layer 62 may be formed as high as the top surface of the substrate 10, i.e., such that the top surface of the SiGe epitaxial layer 62 and the top surface of the substrate 10 are coplanar. Alternatively, the SiGe epitaxial layer 62 may be formed to overfill the trench 60 such that its top surface is locate at a level above that of the top surface of the substrate 10.

Next, the SiGe epitaxial layer 62 is heavily doped with impurity ions, using an ion implantation process, and a thermal process for activating the impurity ions is performed. Alternatively, the SiGe epitaxial layer 62 may be heavily doped in situ, followed by the thermal process.

The subsequent steps are similar to the corresponding steps described in connection with the first embodiment, and thus will be only briefly described hereinafter. Referring to FIG. 12, an interlayer dielectric layer 40 is formed on the substrate 10 to bury the dummy gate stack 15, and a planarization process is performed until a top surface of the dummy gate electrode layer 14 is exposed. Next, the dummy gate electrode layer 14 is removed.

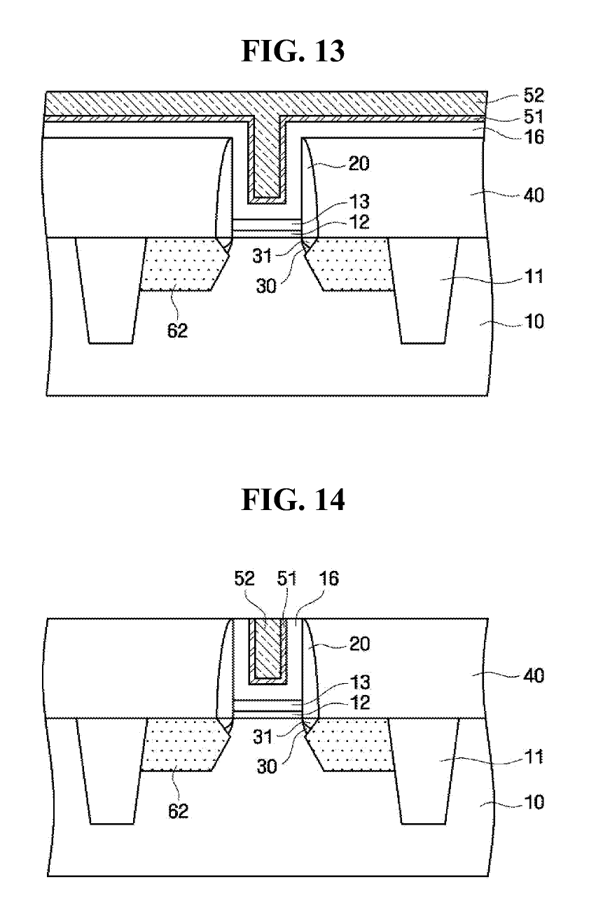

Referring to FIG. 13, a third gate insulating layer 16 is formed on the substrate 10 including over the exposed second gate insulating layer 13. Next, a post nitridation annealing (PNA) process for supplying the third gate insulating layer 16 with nitrogen or a post deposition annealing (PDA) process for activating the third gate insulating layer 16 may be performed. Next, a first gate electrode layer 51 and a second gate electrode layer 52 are sequentially formed on the substrate 10 including over the third gate insulating layer 16.

Referring to FIG. 14, a planarization process is performed until a top surface of the interlayer dielectric layer 40 is exposed.

Note, in the example of this embodiment described above with reference to FIGS. 1 and 2 and 10 to 14, the second gate insulating layer 13 is not removed. Alternatively, in another example of this embodiment, the second gate insulating layer 13 is removed as in the embodiment shown in and described with reference to FIGS. 1 to 4 and 7 to 9.

Finally, embodiments of the inventive concept have been described above in detail. The inventive concept may, however, be embodied in many different forms and should not be construed as being limited to those described above. Rather, these embodiments and examples thereof were described so that this disclosure is thorough and complete, and fully conveys the inventive concept to those skilled in the art. Thus, the true spirit and scope of the inventive concept is not limited by the embodiments described above but by the following claims.

What is claimed is:

1. A method of fabricating a semiconductor device comprising:
sequentially forming a first gate insulating layer and a second gate insulating layer on a substrate;
forming a source and drain region including by implanting impurity ions into a region in the substrate, and performing a first thermal process for activating the impurity ions; and
forming a third gate insulating layer on the substrate after the first thermal process has been performed.

2. The method of claim 1, wherein the first gate insulating layer is formed of a silicon oxide layer, a silicon nitride layer, or a silicon oxynitride layer.

3. The method of claim 2, wherein the second and third gate insulating layers are each formed of high-k dielectric material.

4. The method of claim 3, wherein the second gate insulating layer is formed to a thickness of 5 Å or less.

5. The method of claim 3, further comprising removing the second gate insulating layer after the source and drain region has been formed.

6. The method of claim 3, further comprising subjecting the substrate to a second thermal process after the second gate insulating layer has been formed but before the source and drain region has been formed.

7. The method of claim 3, wherein the first thermal process is rapid thermal annealing (RTA), spike rapid thermal annealing (SRTA), laser spike annealing (LSA) or a flash rapid thermal process (FRTP).

8. The method of claim 3, further comprising forming a gate electrode on the third gate insulating layer, the gate electrode comprising a metal.

9. A method of fabricating a semiconductor device comprising:
sequentially forming a first gate insulating layer, a second gate insulating layer and a dummy gate electrode layer on a substrate;
forming a source and drain region including by implanting impurity ions into a region in the substrate, and performing a first thermal process to activate the impurity ions;
removing the dummy gate electrode layer; and
sequentially forming a third gate insulating layer and an electrically conductive gate electrode layer on the substrate, including directly over the area of the substrate from which the dummy gate electrode layer has been removed.

10. The method of claim 9, wherein the first gate insulating layer is formed of a silicon oxide layer, a silicon nitride layer, or a silicon oxynitride layer, and the second and third gate insulating layers are each formed of high-k dielectric material.

11. The method of claim 9, further comprising performing a post nitridation annealing (PNA) process or a post deposition annealing (PDA) process after the third gate insulating layer has been formed but before the gate electrode layer has been formed.

12. The method of claim 12, wherein the PNA or PDA process is performed at 800° C. or less.

13. The method of claim 9, wherein the forming of the source and drain region further includes:
forming a trench in the substrate; and
forming an SiGe epitaxial layer in the trench; and
wherein the impurity ions are implanted into the SiGe epitaxial layer.

14. The method of claim 9, wherein the second gate insulating layer is formed to a thickness of 5 Å or less.

15. The method of claim 9, further comprising removing the second gate insulating layer after the source and drain region has been formed.

16. A method of fabricating a semiconductor device, comprising:
forming a stack structure, on a substrate, comprising a first insulating layer, a second insulating layer on the first insulating layer, and a dummy electrode layer on the second insulating layer, the second insulating layer being of high-k dielectric material;
implanting impurity ions into a region in the substrate using the stack structure as an ion implantation mask;
thermally treating the substrate, by heating the substrate to a temperature within a range of 800 to 1300° C., to activate the impurity ions;
removing the dummy gate electrode layer;
forming a third insulating layer over the first insulating layer after the thermal treatment has been completed and the dummy gate electrode layer has been removed, the third insulating layer being of high-k dielectric material; and
forming an electrically conductive layer on the third insulating layer.

17. The method of claim 16, wherein high-k dielectric material of the third insulating layer is formed directly on high-k dielectric material of the second insulating layer.

18. The method of claim 17, further comprising subjecting the substrate to a thermal process to cure defects in the first insulating layer at the interface between the first and second insulating layers, before the dummy electrode gate layer of the stack structure is formed, and
wherein the thermal treatment to activate the impurity ions is performed after the dummy gate electrode layer has been formed.

19. The method of claim 16, further comprising removing the second insulating layer, and wherein the high-k dielectric material of the third insulating layer is formed directly on the first insulating layer after the second insulating layer has been removed.

20. The method of claim 19, further comprising subjecting the substrate to a thermal process to cure defects in the first insulating layer at the interface between the first and second insulating layers, before the second insulating layer is removed.
